(19) United States
(12) Patent Application Publication
(10) Pub. No.: US 2005/0268857 A1
(43) Pub. Date: Dec. 8, 2005

(54) Uniformly compressed process chamber gate seal for semiconductor processing chamber

(75) Inventors: Won B. Bang, Santa Clara, CA (US); Yen-Kun Victor Wang, Fremont, CA (US); Lawrence Chung-Lai Lei, Milpitas, CA (US)

Correspondence Address: Patent Counsel;Applied Materials, Inc., Legal Affairs Department, P.O. Box 450A, M/S 2061, Santa Clara, CA, 95052, US

(73) Assignee: APPLIED MATERIALS, INC.

(21) Appl. No.: 11/003,115

(22) Filed: Dec. 3, 2004

Related U.S. Application Data
(60) Provisional application No. 60/576,834, filed on Jun. 2, 2004.
(60) Provisional application No. 60/576,737, filed on Jun. 2, 2004.

(51) Int. Cl. C23C 16/00

(52) U.S. Cl. 118/733

(57) ABSTRACT

Techniques for a door system for sealing an opening between two chambers in a semiconductor processing system are described. The opening has at least one angled corner. The door system includes a door, actuator, and sealing member. The door is moveable in the plane and has at least one angled corner to align the door with the opening. The actuator moves the door to selectively open and close the opening. The sealing member seals the opening when the door is in a closed position. The door is sized to apply substantially uniform seal compression to the sealing member when in the closed position.

### CROSS-REFERENCES TO RELATED APPLICATIONS

The present application claims the benefit of U.S. provisional patent application 60/576,834, filed Jun. 2, 2004, entitled “Uniformly Compressed Process Chamber Gate Seal for Semiconductor Processing Chamber” (Attorney Docket No. A9021/T566) and U.S. Provisional Patent Application No. 60/576,737, filed Jun. 2, 2004, entitled “Variable Seal Pressure Slit Valve Doors for Semiconductor Manufacturing Equipment” (Attorney docket No. A8822T546), both of which are incorporated herein by reference for all purposes.

### BACKGROUND OF THE INVENTION

The present invention generally relates to the construction of vacuum processing chambers used for processing substrates, and more specifically to techniques for uniformly compressed sealing members for slit valve doors with angled corners.

In general, vacuum processing chambers for processing substrates include a substrate transfer opening, commonly known as a slit valve. A slit opening, a tunnel-like passage associated with the slit valve, is used to transfer substrates between a process chamber, also called a reactor chamber, and a transfer chamber. The slit valve opening is commonly sealed at an outside surface of the process chamber body by a blocking plate which moves over the slit valve opening. This blocking plate is a conventional slit valve door. An o-ring is generally attached to the conventional slit valve door to provide a seal.

In a conventional vacuum processing chamber, the slit valve door may have angled corners. When closing such a slit valve door, the angled corners of the slit valve door are aligned by angled corners of the slit valve seat. To provide alignment, the dimensions of the seat are sized smaller, generally by at least about 0.008 inches on each of the two sides used for alignment, than the slit valve door. However, this implementation results in tensile (and shear) stresses. As shown in FIG. 1, as a conventional slit valve door closes, it initially contacts the slit valve seat at loading surfaces of the angled corners due to the size difference. The actuation force used to close the slit valve door and maintain a seal (FACTUATION PRESSURE) is concentrated on the relatively small loading surfaces. At these loading surfaces, a localized stress, or shear force, develops due to the incident angle of the actuation force to the angled corner of the slit valve seat.

When a conventional slit valve door is in the closed position, the o-ring generates particle contaminants at the angled corners of the slit valve door. These particles can contaminate the process chamber and damage substrates. Until now there has been no satisfactory solution to overcome o-ring contaminants for a slit valve door with angled corners, in that conventional vacuum processing chambers are constructed in a configuration that gives rise to particles from o-rings in the process chamber.

### BRIEF SUMMARY OF THE INVENTION

The present invention recognizes that the severity of chemical attack on the sealing member is dependent on the level of tensile (or shear) stress on the sealing member. In conventional systems, where high localized stresses are present at the angled corners, the chemical attack is accelerated. Embodiments of the present invention provide techniques for a door system with angled corners for sealing an opening between two chambers in a semiconductor processing system. The slit valve door is sized to apply substantially uniform seal compression to the sealing member when in the closed position. In this way, the stress experienced by the sealing member at the angled corners is substantially reduced, and so is the chemical attack. Consequently, degradation of the sealing member is diminished and particle contamination is decreased.

According to an embodiment of the present invention, the door system for sealing an opening on a plane between two chambers in a semiconductor processing system where the opening has at least one angled corner, includes a door, actuator, and sealing member. The door is moveable in the plane and has at least one angled corner to align the door with the opening. The actuator moves the door to selectively open and close the opening. The sealing member seals the opening when the door is in a closed position. The door is sized to apply substantially uniform seal compression to the sealing member when in the closed position.

According to an another embodiment, a system for sealing an opening on a plane between two chambers in a semiconductor processing system is provided. The system includes a sealing member disposed along a border of the opening and means, moveable in the plane of the opening between an open position and a closed position, for applying a substantially uniform seal compression to the sealing member to seal the opening in the closed position.

According to yet another embodiment, a method of performing a semiconductor manufacturing process in at least one chamber. A substrate is placed in a chamber. A door is provided, as well as a sealing member between the door and an opening of the chamber. The door is moved to close the opening. Substantially uniform sealing pressure is applied to the sealing member.

The foregoing, together with other features, embodiments, advantages of the present invention, will become more apparent when referring to the following specification, claims, and accompanying drawings.

### BRIEF DESCRIPTION OF THE DRAWINGS

FIG. 1 shows a conventional slit valve and slit valve door.

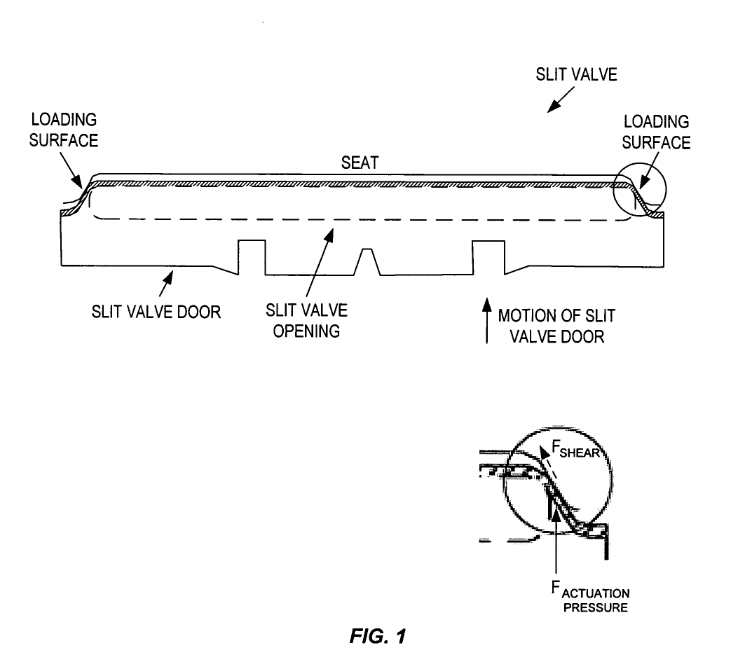

FIG. 2 is a simplified block diagram illustrating an exemplary vacuum processing chamber system according to an embodiment of the present invention.

FIG. 3 is a front view of the slit valve and slit valve door according to an embodiment of the present invention.

FIG. 4 is a cross-sectional view of a slit valve and slit valve door according to an embodiment of the present invention.

FIGS. 5(a) and 5(b) are cross-sectional views of the slit valve door according to an embodiment of the present invention in an open and closed position, respectively.

FIG. 6 is a simplified diagram showing actuation forces applied to a slit valve door according to an embodiment of the present invention in the closed position.

### DETAILED DESCRIPTION OF THE INVENTION

Embodiments of the present invention provide techniques for a door system for sealing an opening between two chambers in a semiconductor processing system and, more particularly, techniques to substantially reduce particle contaminants from a slit valve o-ring with angled corners due localized stresses. The inventors recognize that slit valve o-rings, generally perfluoro elastomers, are chemically attacked more severely when under tensile (or shear) stress by chemical species used during the chamber cleaning process, such as fluorine and nitrogen trifluoride (NF3). Accordingly, the present approach diminishes, or avoids, localized shear stresses by providing uniform compression to the sealing member. Other techniques to reduce particle contaminants resulting from o-ring chemical attack are discussed in U.S. Provisional Patent Application No. 60/576,737, filed Jun. 2, 2004, entitled “Variable Seal Pressure Slit Valve Doors for Semiconductor Manufacturing Equipment” (Attorney docket No. A8822T546), which is incorporated herein by reference for all purposes.

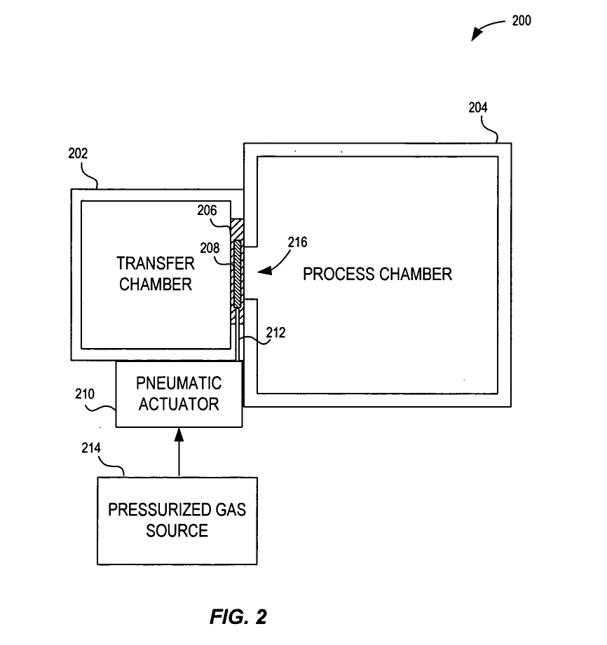

FIG. 2 is a simplified block diagram illustrating an exemplary vacuum processing chamber system 200 according to an embodiment of the present invention. Transfer chamber 202 is connected to process chamber 204 through a slit valve 206 and slit valve opening 216.

Slit valve 206 has a slit valve door 208 movable in a direction generally parallel to the plane of the slit valve opening 216. Rods 212 connect slit valve door 208 to the pneumatic actuator 210. In order to move rods 212, and thus slit valve door 208, the pneumatic actuator 210 applies or relaxes sealing pressure to rods 212.

Pressurized gas is provided to pneumatic actuator 210 from pressurized gas source 214. The pressure level supplied by the pressurized gas source 214 is at least the maximum pressure level needed by vacuum processing chamber system 200. Pressurized gas source 214 can typically provide gas at about 80 psi to about 90 psi since semiconductor fabrication facilities generally provide pressurized gas lines operating at about 80 psi to about 90 psi.

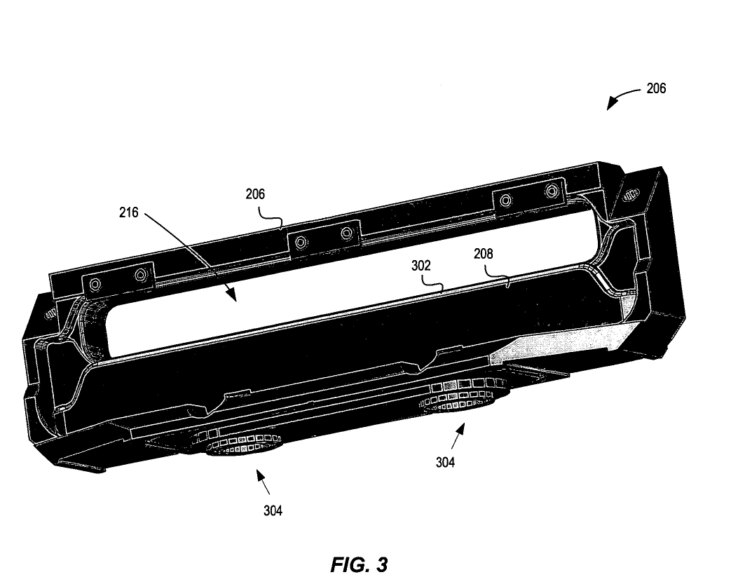

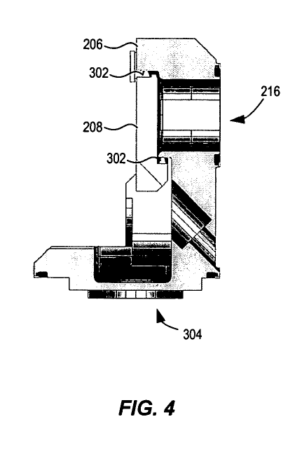

FIG. 3 is a front view of slit valve 206 and slit valve door 208 according to an embodiment of the present invention. FIG. 4 is a cross-sectional view of a slit valve and slit valve door according to an embodiment of the present invention. As illustrated in FIGS. 3 and 4, sealing member 302 is attached to slit valve door 208. When the slit valve door 208 is in the closed position, sealing member 302 surrounds the circumference of silt valve opening 216 to form a seal. While in one embodiment, sealing member 302 is a perfluoro elastomeric o-ring, in other embodiments, sealing member 302 may be any suitable sealing device with elastic properties.

FIG. 3 also shows travel tubes 304. Travel tubes 304 allow rods 212 to pass through slit valve 206 and attach to slit valve door 208. Although two travel tubes 304 are depicted for two rods 212, one of ordinary skill will recognize that the present invention can use one, two, three, or more rods 212, and may accordingly required a corresponding number of travel tubes 304.

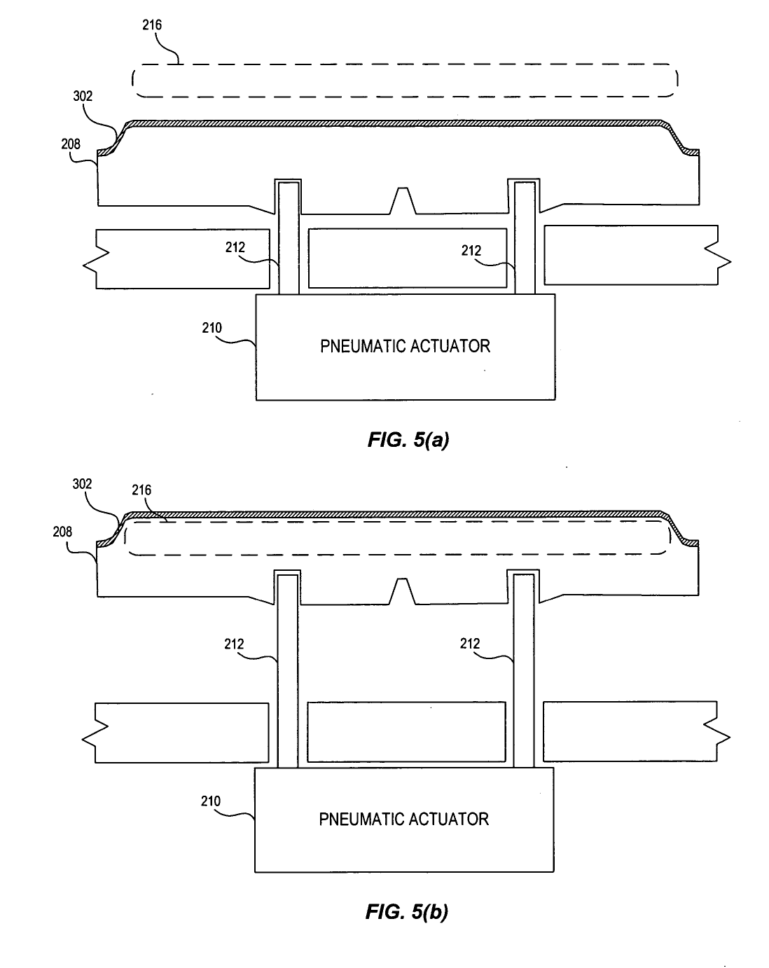

FIG. 5(a) illustrates slit door 208 in an open position to allow substrates to pass between transfer chamber 202 to process chamber 204 through the slit valve opening 216.

FIG. 5(b) illustrates slit door 208 in a closed position to seal transfer chamber 202 from process chamber 204. Rods 212, which pass through travel tubes 304, are attached to slit door 208. To close slit door 208, rods 212 are extended by pneumatic actuator 210.

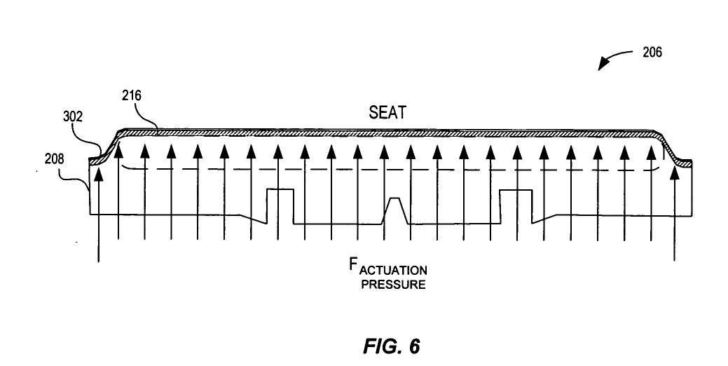

FIG. 6 is a simplified diagram showing the actuation forces applied to a slit valve door according to an embodiment of the present invention in the closed position. Since slit valve door 208 is sized to closely match the seat of the slit valve, the actuation forces are uniformly distributed (e.g., variation in sealing pressure on the sealing member of less than 20%, preferably less than 10%, and more preferably less than 5%) along most or all of an entire edge of the slit valve door 208, thereby avoiding the high localized stresses experienced in conventional systems. In one embodiment, the slit valve seat provides less than about 0.004 inches of compression on each side used for alignment. With this level of seat to door compression, a seal between two chambers can be maintained by a sealing member during typical semiconductor manufacturing environments, including a pressure gradient of 760 torr or more between the two chambers.

### EXAMPLES

To prove the principle and operation of the present invention, the inventors performed experiments. These experiments were merely examples and should not unduly limit the scope of the inventions defined by the claims herein. One of ordinary skill in the art would recognize many other variations, modifications, and alternatives. Uniformly compressed sealing members for slit valve doors were demonstrated. Slit valve seats providing 0.004 inches and 0.003 inches of compression were machined and tested under conditions simulating a wafer deposition process and a chamber clean process. During the deposition and chamber clean processes, the pressure gradients between the process and transfer chambers were approximately 760 torr and 10 torr, respectively. While monitoring the slit valve doors for leaks, the sealing pressures applied to the slit valve doors were adjusted from 5 psi to 25 psi in increments of 5 psi. The results of the results of these experiments are provided below in Table 1.

TABLE 1

| Chamber Clean Process | | | Deposition Process | | |
|---|---|---|---|---|---|
| (10 torr pressure gradient) | | | (760 torr pressure gradient) | | |
| | Slit Valve Leak | | | Slit Valve Leak | |
| | Slit Valve with | Slit Valve with | | Slit Valve with | Slit Valve with |
| Pressure | 3 mil of | 4 mil of | Pressure | 3 mil of | 4 mil of |
| (psi) | compression | compression | (psi) | compression | compression |
| 25 | No | No | 25 | No | No |
| 20 | No | No | 20 | No | No |
| 15 | No | No | 15 | No | No |
| 10 | No | No | 10 | No | Yes |
| 5 | No | No | 5 | Yes | Yes |

As can be seen in Table 1, slit valves configured to provide uniform compression to the sealing member can seal a slit valve opening between two chambers in a semiconductor processing system during deposition processing. Meanwhile, the sealing pressure is uniformly distributed along the entire edge of the slit valve seat, thereby avoiding the localized stresses recognized by the inventors in conventional systems. The inventors have found that the reduction of these localized stresses increases the longevity of sealing members and reduces particle contaminants created by sealing members. In fact, an embodiment of the present invention has extended the lifetime of a sealing member from about 3000 to greater than 12000 wafer cycles.

Although specific embodiments of the invention have been described, various modifications, alterations, alternative constructions, and equivalents are also encompassed within the scope of the invention. The described invention is not restricted to operation within certain chamber processing environments, but is free to operate within a plurality of processing environments. Additionally, although the present invention has been described using a particular series of steps, it should be apparent to those skilled in the art that the scope of the present invention is not limited to the described series of steps.

Further, while the present invention has been described using a particular combination of hardware and software in the form of control logic and programming code and instructions, it should be recognized that other combinations of hardware and software are also within the scope of the present invention. Aspects of the present invention may be implemented only in hardware, or only in software, or using combinations thereof.

It is understood that the examples and embodiments described herein are for illustrative purposes only and that various modifications or changes in light thereof will be suggested to persons skilled in the art and are to be included within the spirit and purview of this application and scope of the appended claims.

1. A door system for sealing an opening on a plane between two chambers in a semiconductor processing system where the opening has at least one angled corner, the door system comprising:
a door moveable in the plane, the door having at least one angled corner to correspond to the at least one angled corner of the opening;
an actuator to move the door to selectively open and close the opening; and
a sealing member to seal the opening when the door is in a closed position;
wherein the door is sized to apply a substantially uniform seal compression to the sealing member when in the closed position.

2. The system of claim 1 wherein the sealing member comprises an o-ring.

3. The system of claim 2 wherein the o-ring comprises a perfluoro elastomer.

4. The system of claim 1 wherein the door comprises two angled corners corresponding to two angled corners of the opening.

5. The system of claim 4 wherein the two angled corners of the opening being located at an end of the opening and disposed on opposite sides of the end.

6. The system of claim 4 wherein the door in the closed position provides less than 20% variation in seal compression to the sealing member.

7. The system of claim 1 wherein the sealing member is mounted along edges of the door.

8. The system of claim 1 wherein the door is a slit door.

9. The system of claim 1 wherein a gradient pressure between the two chambers is in a range of about 0.3 torr to about 760 torr.

10. A system for sealing an opening on a plane between two chambers in a semiconductor processing system, comprising:
a sealing member disposed along a border of the opening; and
means, moveable in the plane of the opening between an open position and a closed position, for applying a substantially uniform seal compression to the sealing member to seal the opening in the closed position.

11. The system of claim 10 wherein the sealing member comprises an o-ring.

12. The system of claim 11 wherein the o-ring comprises a perfluoro elastomer.

13. The system of claim 10 wherein the opening comprises two angled corners, the two angled corners being located at an end of the opening and disposed on an opposite side of the opening from other angled corner.

14. The system of claim 10 wherein a gradient pressure between the two chambers is in a range of about 0.3 torr to about 760 torr.

15. The system of claim 10 wherein the door comprises two angled corners corresponding to two angled corners of the opening.

16. A method of performing a semiconductor manufacturing process in at least one chamber with a door, the method comprising:
placing a substrate in a chamber;
providing the door;
providing a sealing member between the door and an opening of the chamber;
moving the door to close the opening; and
applying a substantially uniform sealing pressure to the sealing member.

17. The system of claim 16 wherein the door comprises two angled corners corresponding to two angled corners of the opening.

18. The system of claim 16 wherein the door in the closed position provides less than 20% variation in seal compression to the sealing member.

19. The system of claim 16 wherein the door is a slit door.

20. The system of claim 16 wherein a gradient pressure between the chamber and another chamber is in a range of about 0.3 torr to about 760 torr.
